(19) United States
(12) Patent Application Publication
(10) Pub. No.: US 2010/0101937 A1
(43) Pub. Date: Apr. 29, 2010

(54) METHOD OF FABRICATING TRANSPARENT CONDUCTIVE FILM

(75) Inventors: Chien-Min Weng, Tao-Yuan (TW); Tzu-Wen Chu, Tao-Yuan (TW); Chiao-Ning Huang, Tao-Yuan (TW); I-Wen Lee, Tao-Yuan (TW); Shih-Liang Chou, Tao-Yuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Applied Vacuum Coating Technologies Co., Ltd., Tao-Yuan (TW)

(21) Appl. No.: 12/260,092

(22) Filed: Oct. 29, 2008

(51) Int. Cl. C23C 14/34

(52) U.S. Cl. 204/192.1

(57) ABSTRACT

A method of fabricating transparent conductive film including the following steps is provided. First, a reactive chamber having at least a target and at least a heating device is provided. Subsequentially, a plasma is generated in the reactive chamber, wherein the plasma is located above the target. Next, the plasma is heated by the heating device from a standby temperature to a working temperature. Simultaneously, a hard plastic substrate is passed above the plasma at a specific speed, wherein the particles of the target are bombarded by the plasma so as to form transparent conductive film on the hard plastic substrate.

### BACKGROUND OF THE INVENTION

1. Field of the Invention

The present invention relates to a method of fabricating conductive film. More particularly, the present invention relates to a method of fabricating transparent conductive film.

2. Description of Related Art

With the gradual development in the semiconductor technology, transparent conductive film has been widely applied in electronic devices of various fields. For example, transparent conductive film is applied in the fields such as the pixel electrodes and the opposite electrodes used to maintain a display voltage in a liquid crystal display and the sensor electrodes in a touch panel. The components of transparent film are mostly metal oxide layers such as Indium Tin Oxide (ITO) or Indium Zinc Oxide (IZO), which have the characteristics of both light transmittance and conductivity at a certain optical thickness.

A touch panel is illustrated below as an example. FIG. 1 is a schematic view of a touch panel. Referring to FIG. 1, a touch panel 100 includes, for example, a supported substrate 102, a first transparent conductive film 104, a second transparent conductive film 106, and a plurality of spacers 108. The first transparent conductive film 104 is required to be disposed on the harder supported substrate 102 and then the spacers 108 as well as the second transparent conductive film 106 are sequentially disposed thereon. The first transparent conductive film 104 and the second transparent conductive film 106 generally comprise polyethylene terephthalate film (PET film) coated with transparent conductive film.

The user's press-down action enables the second transparent conductive film 106 to touch the first transparent conductive film 104 there below, and thus a corresponding signal is generated. Therefore, the supported substrate 102 has to be provided with a certain mechanical strength and the physical properties to prevent erroneous signals generated from a touch action of the touch panel 100 or an error in signal transmission due to an accidental touch action. For example, the supported substrate 102 is usually a glass substrate or a hard plastic substrate such as a polycarbonate substrate.

A glass substrate can maintain at a higher temperature so when a glass is selected as the supported substrate 102, the first transparent conductive film 104 is directly coated on the glass substrate, for example. However, the glass substrate is too brittle to extra work and also may increase weight of the touch panel 100.

A hard plastic substrate such as a polycarbonate substrate has lighter weight and may be more easily cut but cannot maintain at a high temperature under a sputtering process. Therefore, when a polycarbonate (PC) is selected as the supported substrate 102, the first transparent conductive film 104 has to be PET film coated with transparent conductive film. In addition, the PET film coated with transparent conductive film must additionally undergo a laminating process so as to be laminated to the hard plastic substrate. As a result, the laminating process which transfers the PET film with transparent conductive film onto the PC increases manufacturing costs and decreases yield due to the laminating process. Accordingly, not only do the manufacturing costs add up but also the thickness of the touch panel 100 increases, resulting in low transmittance of the visible light.

### SUMMARY OF THE INVENTION

The present invention provides a method of fabricating transparent conductive film to solve the problem that a hard plastic substrate cannot be used in a conventional sputtering process of fabricating transparent conductive film.

The present invention provides a method of fabricating transparent conductive film including the following steps. First, a reactive chamber is provided, wherein the reactive chamber has at least a target and at least a heating device. Then, a plasma is generated in the reactive chamber above the target. Next, the plasma is heated from a standby temperature to a working temperature using the heating device. In addition, a hard plastic substrate passed above the plasma under a specific speed, wherein the target particles will be bombarded by the plasma, are deposited on the hard plastic substrate in a sputtering manner to form a transparent conductive film.

In one embodiment of the present invention, the abovementioned standby temperature is 0° C.˜200° C.

In one embodiment of the present invention, the abovementioned working temperature is 0° C.˜450° C.

In one embodiment of the present invention, the abovementioned fabricating method further includes a pre-treatment process on the hard plastic substrate before passing the hard plastic substrate above the plasma. The pre-treatment process includes, for example, coating a primer layer of several tens of nanometers in thickness on the hard plastic substrate. The components of the primer layers such as chromium (Cr), silicon (Si), silicon oxide, or a combination thereof.

In one embodiment of the present invention, the abovementioned fabricating method further includes a pre-heating process on the hard plastic substrate before passing the hard plastic substrate above the plasma. For example, the temperature of the pre-heating process is 70° C. to 130° C.

In one embodiment of the present invention, the material of the abovementioned hard plastic substrate is polycarbonate (PC).

In one embodiment of the present invention, the material of the abovementioned target includes metal oxides comprising different ratios of Indium-Tin or Indium-Zinc Oxide.

In one embodiment of the present invention, the higher the working temperature is, the higher the specific speed is, while the lower the working temperature is, the slower the specific speed is.

In the present invention, when the hard plastic substrate is passed through the reactive chamber, the hard plastic substrate is instantly heated. Such instantly high temperature environment will get the better physical and electrical properties of the transparent conductive film. In addition, the period of time that the hard plastic substrate is passed through the reactive chamber may also be adjusted in response to different temperatures of the reactive chamber to prevent the plastic substrate from deformation. As such, the present invention provides a method of fabricating transparent conductive film on a hard plastic substrate.

In order to the make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the descriptions, serve to explain the principles of the invention.

FIG. 1 is a schematic view of a conventional touch panel.

FIG. 2 is a top view illustrating the flow of fabricating transparent conductive film in one embodiment of the present invention.

FIG. 3 is a lateral view illustrating the flow of fabricating transparent conductive film in one embodiment of the present invention.

FIG. 4 illustrates a comparison of the crystallization of transparent conductive film in one embodiment of the present invention.

FIG. 5 illustrates a touch panel of one embodiment of the present invention.

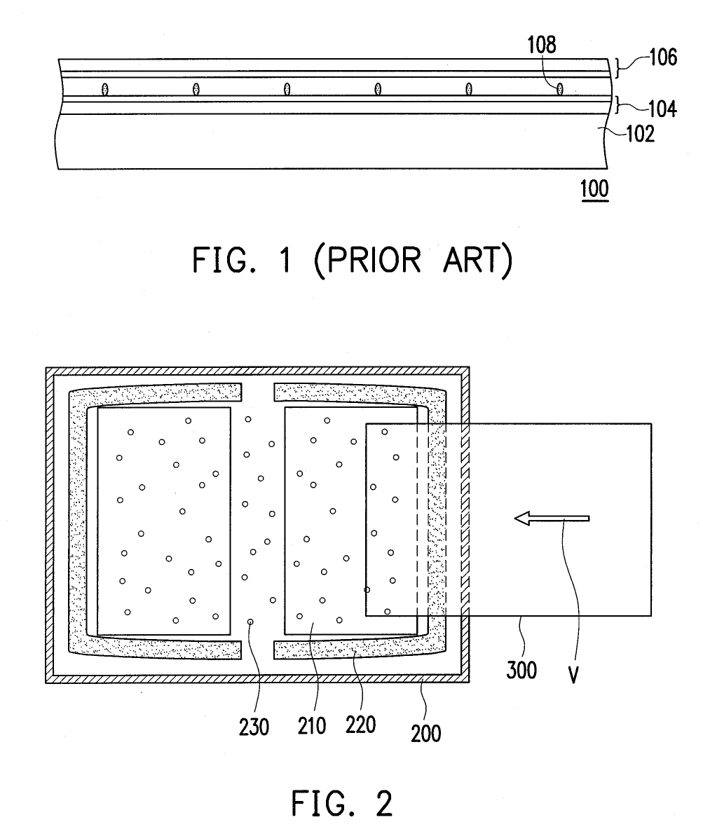

### DESCRIPTION OF EMBODIMENTS

A plastic substrate is only capable of bearing a low range of working temperature so transparent conductive film cannot be coated on a plastic substrate directly using a conventional sputtering process. Thus, the application aspect of a plastic substrate is greatly limited. Based on the above reason, the present invention provides a method of fabricating transparent conductive film, wherein the transparent conductive film is directly formed on a hard plastic substrate and has good conductivity. In addition, the hard plastic substrate adopted in the method of the present invention will not be deformed or damaged due to the heat.

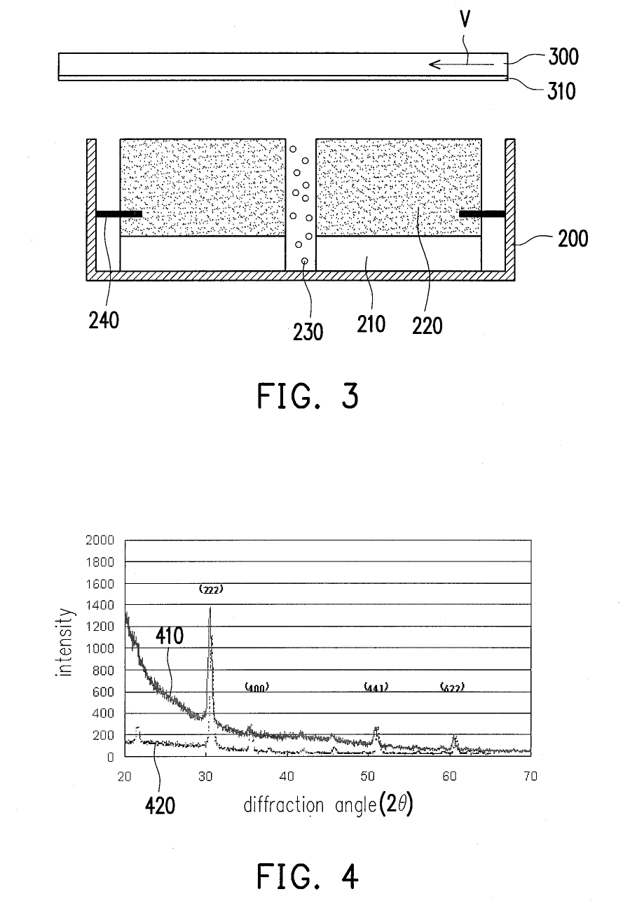

FIG. 2 is a top view illustrating the flow of fabricating transparent conductive film in one embodiment of the present invention. FIG. 3 is a lateral view illustrating the flow of fabricating transparent conductive film in one embodiment of the present invention. Referring to both FIG. 2 and FIG. 3, the method of fabricating transparent conductive film of the present invention includes the following steps. First, a reactive chamber 200 is provided, wherein the reactive chamber 200 has at least a target 210 and at least a heating device 220. Material of the target 210 may include metal oxides comprising different ratios of Indium-Tin or Indium-Zinc Oxide and may certainly be other conductive materials, which are not limited by the present invention herein.

In one embodiment, the component ratio of Indium-Tin and Indium-Zinc Oxide in the target 210 may be adjusted according to different fabricating processes or product requirements. For example, the ratio of Tin-Oxide in the target 210 may be 2˜15%. However, the abovementioned ratio is merely for the purpose of illustration and is not intended to limit the scope of the present invention.

Then, plasma 230 is generated in the reactive chamber 200 above the target 210, for example. The plasma 230 comprises particles such as charged gas molecules, gas atoms, and electrons, for example. The particles in the plasma 230 have been excited to bombard the surface of the target 210 to induce the particles of the target 210 to spray out and then deposit on a surface of another material in a sputtering manner so as to achieve a sputtering effect. In the present embodiment, the plasma 230 is maintained in a standby mode after being generated in the reactive chamber 200. At this time, the standby temperature in the reactive chamber 200 is, for example, 0° C.˜200° C.

Afterward, the plasma 230 is heated from the standby temperature to a working temperature with a heating device 220 and a hard plastic substrate 300 is simultaneously passed above the plasma 230. At this time, the plasma 230 bombards the target 210 to induce the particles on the surface of the target 210 to spray out and then deposit on the hard plastic substrate 300 in a sputtering manner to form a transparent conductive film 310. In this step, the reactive chamber 200 is heated to a working temperature of 0° C.˜450° C.

In the present embodiment, the heating device 220 mainly heats the plasma 230 to enable both the plasma 230 and the particles spraying from the target 210 to have higher energy. As such, the particles bombarded from the target 210 may form the transparent conductive film 310 with better mechanical strength and physical properties on the hard plastic substrate 300.

In general, the transparent conductive film 310 has better physical properties, for example, low conductivity resistance. Therefore, the present embodiment uses an instant heating process to enable the particles bombarded from the target 210 to have higher energy so that the transparent conductive film 310 with better conductivity may be formed. In addition, the hard plastic substrate 300 is passed above the plasma 230 under a specific speed V and is not stationary above the plasma 230. Therefore, the hard plastic substrate 300 is not deformed due to being overheated. In other words, in the present embodiment, the transparent conductive film 310 is formed on the hard plastic substrate 300 without deformation of the hard plastic substrate 300.

It should be noted that the specific speed V that the hard plastic substrate 300 is passed above the plasma 230 actually relates to the control of the working temperature in the environment. When the working temperature gets higher, the specific speed V that the hard plastic substrate 300 is passed above the plasma 230 is increased as well. Conversely, the specific speed V that the hard plastic substrate 300 is passed above the plasma 230 may be slower. The hard plastic substrate 300 may be placed on a carrier, and then the specific speed V that the hard plastic substrate 300 is passed above the plasma 230 may be controlled by controlling the speed of the carrier.

In the present embodiment, in order to monitor the temperature changes in the reactive chamber 200, a temperature sensor 240 may be disposed in the reactive chamber 200. The temperature sensor 240 may be a thermocouple extended into the reactive chamber 200 to detect temperature changes of the plasma 230. Certainly, the temperature sensor 240 may be other temperature sensing device, which is not limited by the present invention herein. Furthermore, the present embodiment sets the working temperature range to be 0° C.˜450° C. as an example. However, the working temperature may be adjusted according to various requirements in other embodiments. In summary, the higher the working temperature is, the higher the energy the plasma 230 gets. The conductivity of the transparent conductive film 310 is also significantly increased. However, it is limited to the low heat resistance of the hard plastic substrate itself. Therefore, in the fabricating method of the present embodiment, the working temperature in the environment has to be controlled in an appropriate range and should not be increased without limit.

Prior to performing the abovementioned process, a pre-treatment process may be performed on the hard plastic substrate 300 in the present embodiment to increase adhesion between the transparent conductive film 310 and the hard plastic substrate 300. The process includes forming a primer layer (not shown) on the surface of the hard plastic substrate 300. The components of the primer layer (not shown) include chromium (Cr), silicon (Si), silicon oxide, or a combination thereof. Certainly, the components of the primer layer are not limited to the above. In other steps of the process, other material may be selected as the primer layer (not shown).

In addition, before the hard plastic substrate 300 is passed through the reactive chamber 200, a pre-heating process may be performed on the hard plastic substrate 300 in the present embodiment with a pre-heating process temperature of 70° C. to 130° C., for example. After the pre-heating process, the temperature of the particles bombarded from the target 210 is closer to the temperature of the hard plastic substrate 300 when the hard plastic substrate 300 is passed above the plasma 230. As a result, not only is the mechanical strength of the transparent conductive film 310 enhanced but the physical properties of the overall transparent conductive film 310 are also significantly improved. It should be noted that the material of the hard plastic substrate 300 in the present embodiment is polycarbonate, for example. Therefore, the pre-heating process temperature is lower than 130° C., for example, to prevent the hard plastic substrate 300 from deformation. Furthermore, the material of the hard plastic substrate 300 may also be polymethyl methacrylate (PMMA), polyethylene terephthalate (PET), triacetic acid (TAC), or polyidime (PI). If the hard plastic substrate 300 is made by other materials, the temperature of the pre-heating process may be adjusted accordingly.

To carry the description further, a pre-baking process for the substrate is generally adapted before any process on the hard plastic substrate 300 is performed. Then, the hard plastic substrate 300 is placed in a vacuum chamber to effectively remove the surface moisture. In addition, before the sputtering process on the hard plastic substrate 300, an activation process may be performed thereon, which may be performing a plasma process to activate the surface of the hard plastic substrate 300, for example. The present invention is certainly not limited to the abovementioned pre-treatment processes.

In general, a flexible substrate commonly used in a touch panel requires an additional laminating process in which a plastic film (e.g. PET film) coated with conductive film thereon is laminated to the hard plastic-substrate 300. A possible problem with the laminating process is that the conductive film may easily peel off. In addition, product yield may go down during the laminating process. Compared with conventional designs, the touch panel of the present invention does not require an extra laminating process and thus has better process yield. The touch panel of the present invention uses the present embodiment to form the hard plastic substrate 300 with the transparent conductive film 310 not only enables the touch panel to have better light transmittance but also allows the hard plastic substrate 300 to be easily manufactured and to have lighter weight, which complements drawbacks of a glass substrate.

The transparent conductive film 310 has good physical properties, especially the reliability is significantly increased. The crystallization of the ITO film formed on the PC substrate is comparable to the crystallization of the ITO film formed on a glass substrate. FIG. 4 illustrates a comparison of the crystallization of transparent conductive film in one embodiment of the present invention. Referring to FIG. 4, a diffraction curve 410 illustrates an X-ray crystallization diffraction spectrogram of an ITO film formed on a PC substrate according to the present embodiment and a diffraction curve 420 illustrates an X-ray crystallization diffraction spectrogram of an ITO film formed on a glass substrate according to a conventional method. In general, a glass substrate has the better heat-resistance property so the crystalline level of the ITO film formed on a glass substrate is better than that formed on a PC substrate. Therefore, the peak values of the ITO film at various feature diffraction angles are significant, as shown by diffraction curve 420. It can be seen from FIG. 4, the ITO film formed with the method of the present embodiment also has significant peak values at various feature diffraction angles. Thus, FIG. 4 may further illustrate that the fabricating method of the present embodiment is able to fabricate ITO film with good crystallization.

In addition, in terms of heat and weather resistance properties, the transparent conductive film 310 may also achieve high reliability. For example, a general requirement for a touch panel is that sheet resistance variation of the transparent conductive film 310 is lower than 25% under a high temperature of 80° C. or a temperature of 60° C. and 90% relative humidity for 72˜240 hours. Therefore, the touch panel using the present embodiment to form the hard plastic substrate 300 with the transparent conductive film 310 has better reliability performance. Certainly, the hard plastic substrate 300 with the transparent conductive film 310 formed in the present embodiment is not limited to being applicable in a touch panel.

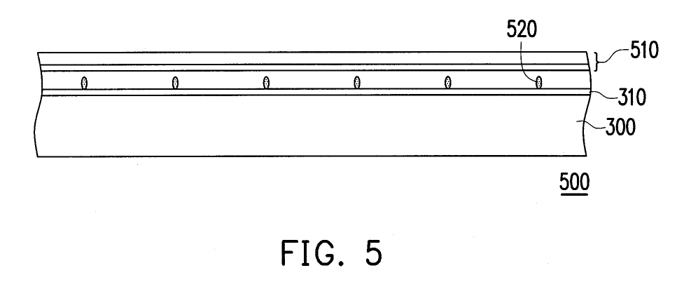

FIG. 5 illustrates a touch panel of one embodiment of the present invention. Referring to FIG. 5, a touch panel 500 includes a hard plastic substrate 300, a transparent conductive film 310, a transparent conductive film 510, and a plurality of spacers 520. The transparent conductive film 310 is formed by using the abovementioned processes and directly disposed on the hard plastic substrate 300. The transparent conductive film 510 is disposed on the hard plastic substrate 300 and the transparent conductive film 310. The spacers 520 are disposed between the transparent conductive film 510 and the transparent conductive film 310. The transparent conductive film 510 comprises PET film coated with conductive film thereon.

In the present embodiment, the transparent conductive film 310 is directly deposited on the hard plastic substrate 300 and is not first coated on the PET film and then laminated onto the hard plastic substrate 300. Therefore, the thickness of the touch panel 500 is less than that of the conventional technology by at least the thickness of the PET film. In addition, the manufacturing process of the touch panel 500 does not require the PET film laminating to the hard plastic substrate 300 so additional problems may not be caused. In other words, the production yield of the touch panel 500 may be further increased.

In light of the above, when the hard plastic substrate is passed above the target, an instant heating process is performed on the reactive chamber to fabricate transparent conductive film of good physical properties and mechanical strength. In the meantime, through controlling the speed of the carrier, deformation of the hard plastic substrate due to overheat of the reactive chamber is prevented. Therefore, the method of fabricating transparent conductive film of the present invention may form transparent conductive film of good physical properties and may also prevent the hard plastic substrate from deformation or damage.

It will be apparent to those of ordinary skills in the technical field that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method of fabricating transparent conductive film, comprising:
providing a reactive chamber, wherein the reactive chamber has at least a target and at least a heating device;
generating a plasma in the reactive chamber, wherein the plasma is above the target; and
heating the plasma from a standby temperature to a working temperature using the heating device and passing a hard plastic substrate above the plasma under a specific speed, wherein particles of the target, after being bombarded by the plasma, are deposited on the hard plastic substrate in a sputtering manner to form a transparent conductive film.

2. The method of fabricating transparent conductive film according to claim 1, wherein the standby temperature is 0° C.˜200° C.

3. The method of fabricating transparent conductive film according to claim 1, wherein the working temperature is 0° C.˜450° C.

4. The method of fabricating transparent conductive film according to claim 1, wherein before passing the hard plastic substrate above the plasma, the method further comprises performing a pre-treatment process on the hard plastic substrate.

5. The method of fabricating transparent conductive film according to claim 4, wherein the pre-treatment process comprises forming a primer layer on a surface of the hard plastic substrate.

6. The method of fabricating transparent conductive film according to claim 5, wherein a material of the primer layer comprises chromium (Cr), silicon (Si), silicon oxide, or a combination thereof.

7. The method of fabricating transparent conductive film according to claim 1, wherein before passing the hard plastic substrate above the plasma, the method further comprises a pre-heating process on the hard plastic substrate.

8. The method of fabricating transparent conductive film according to claim 7, wherein a temperature of the pre-heating process is 70° C. to 130° C.

9. The method of fabricating transparent conductive film according to claim 1, wherein a material of the hard plastic substrate is polycarbonate (PC), polymethyl methacrylate (PMMA), polyethylene terephthalate (PET), triacetic acid (TAC), or polyidime (PI).

10. The method of fabricating transparent conductive film according to claim 1, wherein a material of the target comprises metal oxides with different ratios of Indium-Tin or Indium-Zinc Oxide.

11. The method of fabricating transparent conductive film according to claim 1, wherein a material of the target comprises metal oxides with 2˜15% ratios of Tin-Oxide in Indium-Oxide.

12. The method of fabricating transparent conductive film according to claim 1, wherein the higher the working temperature is, the faster the specific speed is, and the lower the working temperature is, the slower the specific speed is.
